(19) United States
(12) Patent Application Publication
(10) Pub. No.: US 2023/0220550 A1
(43) Pub. Date: Jul. 13, 2023

(54) HEAT TREATMENT APPARATUS, PROCESSING TARGET PROTECTING METHOD, AND STORAGE MEDIUM

(71) Applicant: Tokyo Electron Limited, Tokyo (JP)

(72) Inventors: Morihito INAGAKI, Yamanashi (JP); Jin KUMAGAI, Iwate (JP)

(21) Appl. No.: 18/147,157

(22) Filed: Dec. 28, 2022

(30) Foreign Application Priority Data
Jan. 13, 2022 (JP) 2022-003927

(51) Int. Cl. C23C 16/46; C23C 16/52

(52) U.S. Cl. CPC C23C 16/46; C23C 16/52

(57) ABSTRACT

A heat treatment apparatus includes a processing container that accommodates a processing target; a heater that heats the processing target accommodated in the processing container; and a controller that controls an overall operation of the heat treatment apparatus. The controller controls heating by the heater according to a set temperature of the heater; monitors the processing container in which the processing target is accommodated based on a monitoring condition of a protection function for the processing target; and when an upper limit time of monitoring elapses while the monitoring condition is being satisfied, changes the set temperature of the heater to a set temperature of the protection function.

### CROSS-REFERENCE TO RELATED APPLICATION

This application is based on and claims priority from Japanese Patent Application No. 2022-003927 filed on Jan. 13, 2022 with the Japan Patent Office, the disclosure of which is incorporated herein in its entirety by reference.

### TECHNICAL FIELD

The present disclosure relates to a heat treatment apparatus, a processing target protecting method, and a storage medium.

### BACKGROUND

In a substrate processing apparatus provided with a processing chamber for collectively processing a predetermined number of substrates, an abnormality may occur during transfer of the substrates in a lot processing, and the substrates may stay at a predetermined position in the substrate processing apparatus. For example, the substrates present in the processing chamber where an abnormality has occurred stay still in the processing chamber (see, e.g., Japanese Patent Laid-Open Publication No. 2013-140897).

### SUMMARY

According to an aspect of the present disclosure, a heat treatment apparatus includes a processing container that accommodates a processing target; a heater that heats the processing target accommodated in the processing container; and a controller that controls an overall operation of the heat treatment apparatus. The controller controls heating by the heater according to a set temperature of the heater; monitors the processing container in which the processing target is accommodated based on a monitoring condition of a protection function for the processing target; and when an upper limit time of monitoring elapses while the monitoring condition is being satisfied, changes the set temperature of the heater to a set temperature of the protection function.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 illustrates a cross-sectional view of a film forming apparatus according to an embodiment of the present disclosure.

FIG. 2 illustrates an exploded perspective view of the film forming apparatus according to the embodiment of the present disclosure.

FIG. 3 is a hardware configuration diagram of an example of a computer.

FIG. 4 a diagram illustrating an example of a functional configuration of a control device according to the embodiment.

FIG. 5 is a configuration diagram illustrating an example of parameters of a protection function for a stationary wafer W.

FIG. 6 is a flowchart illustrating an example of processing of a protection function for a stationary wafer W of the film forming apparatus according to the present embodiment.

FIG. 7 is an image diagram of an example of a notification screen.

FIG. 8 is a flowchart of a process execution for a wafer W.

FIG. 9 is a diagram illustrating an example of changes in the elapsed time measured to determine whether a monitoring upper limit time has passed while a monitoring condition is satisfied.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the accompanying drawings. In the present specification and drawings, illustrations and descriptions of parts that are not necessary for the description of the present embodiment are omitted as appropriate.

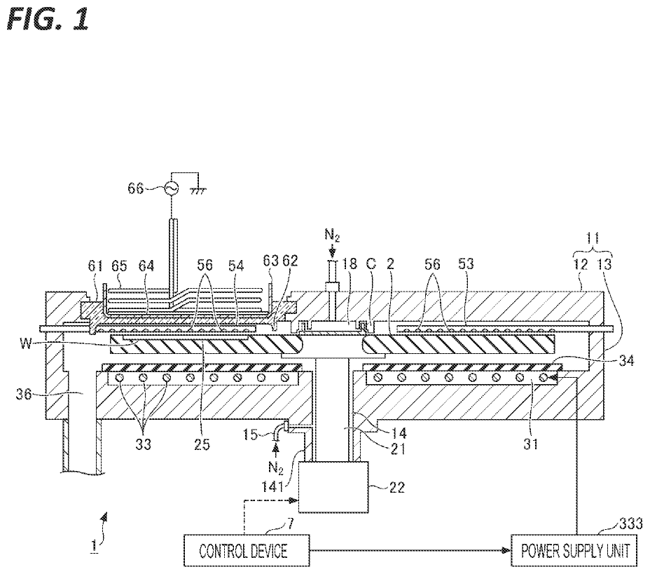

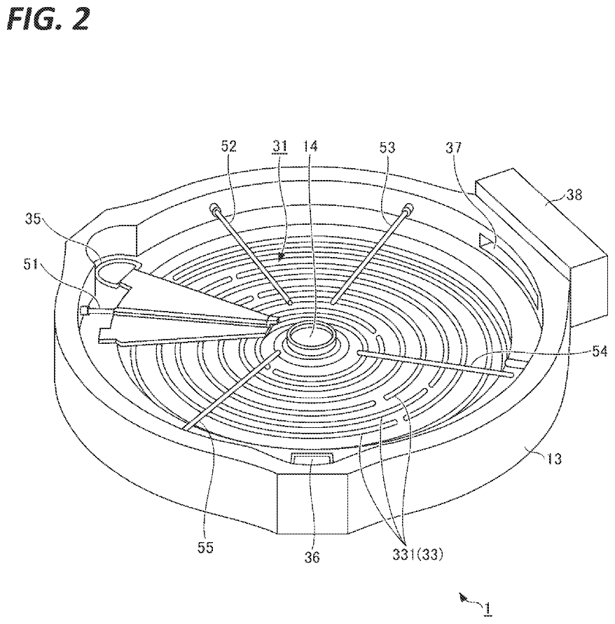

In the present embodiment, descriptions will be made on a film forming apparatus 1 which is an example of a heat treatment apparatus. FIG. 1 illustrates a cross-sectional view of a film forming apparatus according to an embodiment of the present disclosure. FIG. 2 illustrates an exploded perspective view of the film forming apparatus according to the embodiment of the present disclosure.

The film forming apparatus 1 forms a film on a wafer W, which is an example of a processing target. For example, the film forming apparatus 1 causes the wafer W to adsorb the raw material gas, and then supplies an oxidizing gas to the surface of the wafer W to form a molecular layer. The film forming apparatus 1 exposes the wafer W to plasma generated from a plasma generating gas, and performs a process of modifying the molecular layer. The film forming apparatus 1 forms a film by repeatedly performing a series of processes on the wafer W a plurality of times. The raw material gas and the oxidizing gas are examples of a processing gas.

The film forming apparatus 1 includes a substantially circular flat processing container 11 and a disc-shaped rotary table 2 provided in the processing container 11. The rotary table 2 is an example of a stage configured to dispose the wafer W thereon. The processing container 11 includes a top plate 12 and a container body 13 forming side walls and a bottom of the processing container 11.

The rotary table 2 is made of, for example, quartz glass (hereinafter, referred to as quartz), and is provided with a rotary shaft 21 made of metal extending vertically downward at the center. The rotary shaft 21 is inserted into a sleeve 141 having an opening 14 formed in the bottom of the container body 13. The rotary shaft 21 is connected to a rotary drive unit 22 that is provided to airtightly close the processing container 11 at a lower end of the sleeve 141. The rotary table 2 is horizontally supported in the processing container 11 via the rotary shaft 21 and rotated by the action of the rotary drive unit 22.

In order to suppress the raw material gas and the oxidizing gas from flowing from the upper surface to the lower surface of the rotary table 2, a gas nozzle 15 for supplying N₂ (nitrogen) gas to a gap between an opening 14 of the sleeve 141 and the container body 13 and the rotary shaft 21 is provided at the upper end of the sleeve 141.

A center region C is formed on the lower surface of the top plate 12 constituting the processing container 11 to protrude toward the center of the rotary table 2 and have an annular shape in a plan view. A gap between the center region C and the center of the rotary table 2 constitutes a flow path 18 for N₂ gas.

N₂ gas is supplied from a gas supply pipe connected to the top plate 12 to the flow path 18. The N₂ gas that has flowed into the flow path 18 is discharged radially outward of the rotary table 2 over the entire circumference from the gap between the upper surface of the rotary table 2 and the center region C. The N₂ gas suppresses the raw material gas and the oxidizing gas, which are supplied at different positions on the rotary table 2, from contacting each other by taking the center of the rotary table 2 (i.e., the flow path 18) as a bypass.

The exploded perspective view of FIG. 2 illustrates a state in which the top plate 12 and the rotary table 2 are removed from the film forming apparatus 1. A flat annular recess 31 is formed in the bottom surface of the container body 13 positioned below the rotary table 2 along the circumferential direction of the rotary table 2. Heaters 33 are disposed on the bottom surface of the recess 31 over an area facing the entire bottom surface of the rotary table 2. The heater 33 is an example of a heating unit. The heater 33 is sometimes called a stage heater.

The heater 33 is configured by combining a plurality of heater elements 331 each made of an elongated tubular carbon wire heater formed in an arc shape having a length of, for example, ten and several centimeters to several ten centimeters. By combining a plurality of arc-shaped heater elements 331, the heater 33 is disposed in the recess 31 to draw a plurality of concentric circles centered on the rotary shaft 21.

The heater 33 is disposed in a state of floating from the bottom surface of the recess 31 to be substantially parallel to the bottom surface of the recess 31 when viewed from the side. Both ends of the heater 33 are bent downward and connected to a power supply unit 333 provided outside the processing container 11 via a connection port passing through the bottom plate of the container body 13. The power supply unit 333 is controlled by a control device 7. The control device 7 may divide, for example, the heater 33 disposed into regions and adjust the output of the heater 33 for each divided region. The upper surface of the recess 31 in which the heater 33 is disposed is covered with a shield 34 which is an annular plate member made of, for example, quartz.

Further, exhaust ports 35 and 36 for exhausting the inside of the processing container 11 are opened in the bottom surface of the container body 13 located on the outer periphery of the recess 31. A vacuum exhaust mechanism (not illustrated) constituted by a vacuum pump is connected to the exhaust ports 35 and 36.

A loading/unloading port 37 for the wafer W and a gate valve 38 for opening and closing the loading/unloading port 37 are provided on the side wall of the container body 13. The wafer W held by an external transfer mechanism is loaded into the processing container 11 through the loading/unloading port 37. A plurality of recesses 25 forming a mounting area for the wafer W is provided on the upper surface of the rotary table 2 to surround the flow path 18 at the center. The wafer W loaded into the processing container 11 is disposed in each recess 25. The transfer of the wafer W between the transfer mechanism and the recess is performed by lifting pins that may move up and down between the upper position and the lower position of the rotary table 2 via through holes (not illustrated) provided in each recess 25. The description of the lifting pins is omitted.

A raw material gas nozzle 51, a separation gas nozzle 52, an oxidizing gas nozzle 53, a plasma gas nozzle 54, and a separation gas nozzle 55 are disposed above the rotary table 2 at intervals along the rotation direction of the rotary table 2. A plurality of discharge ports 56 is formed on the lower surfaces of the gas nozzles at intervals, and each gas is discharged downward from the discharge ports 56.

A plasma forming portion 61 made of a dielectric material such as quartz, having a planar shape corresponding to the opening, and having a cup-shaped longitudinal side surface is inserted into the opening of the top plate 12. A protrusion 62 is provided along the periphery of the plasma forming portion 61 on the lower surface of the plasma forming portion 61. The plasma gas nozzle 54 is inserted to discharge gas into the area surrounded by the protrusion 62.

A recess is formed on the upper surface of the plasma forming portion 61. A box-shaped Faraday shield 63 whose upper surface is open is disposed in the recess. A plate member 64 for insulation is disposed on the bottom surface of the Faraday shield 63. An antenna 65 for plasma generation, which is formed by coiling a metal wire around a vertical axis and is connected to a radio-frequency power supply 66, is provided on the upper surface.

A film forming apparatus 1 is provided with a control device 7 including a computer for controlling the entire operation of the apparatus. The control device 7 stores a program for controlling the entire operation of the apparatus. By executing the program, the control device 7 transmits a control signal to each part of the film forming apparatus 1 to control the operation of each part. A program is installed in the control device 7 from a storage medium such as a hard disk, compact disk, magneto-optical disk, memory card, or flexible disk. The program may be installed in the control device 7 from a storage medium of an information processing apparatus communicably connected via a network.

For example, the control device 7 controls an adjustment of supply amounts of various gases, an output control of the heater 33, an adjustment of supply amount of N₂ gas, and an adjustment of rotation speed of the rotary table 2 by the rotary drive unit 22. In addition, the control device 7 performs a control related to the protection function of the stationary wafer W. A stationary wafer W is a wafer W left in the processing container 11 due to an error that occurs during the wafer transfer. The protection function of the stationary wafer W suppresses damage due to heating of the stationary wafer W (i.e., damage due to thermal stress).

For example, when an alarm (error) is generated during wafer transfer for loading the wafer W into the processing container 11 or during wafer transfer for unloading the wafer W from the processing container 11, the stationary wafers W left in the processing container 11 continue to be heated by the heater 33 until the film forming apparatus 1 is restored. For this reason, the stationary wafers W left in the processing container 11 due to the generation of an alarm during wafer transfer may be damaged by heating, for example, in an underlying layer.

Therefore, in the present embodiment, the processing container 11 accommodating the wafers W is monitored based on monitoring conditions (to be described later), and when the monitoring upper limit time elapses while the monitoring conditions are satisfied, the set temperature of the heater 33 is lowered. The monitoring conditions may be set such that the stationary wafers W in the processing container 11 are not scraped due to unacceptable damage due to heating from the heater 33.

The stationary wafer W left in the processing container 11 due to the generation of an alarm during wafer transfer is an example. The function of protecting the stationary wafers W in the present embodiment may also be applied to the stationary wafers W left in the processing container 11 due to other factors.

The control device 7 performs a control such that a heat treatment (process) is made on the wafer W based on wafer processing information such as a recipe indicating processing steps for the wafer W. Further, the control device 7 may display a screen for receiving input of information from an operator and a screen for outputting information such as results to the operator. The control device 7 may be built in the film forming apparatus 1 or may be connected to the film forming apparatus 1 via a communication path.

The communication path may be a wired communication system or a wireless communication system, and may be any communication path for exchanging various signals inside and outside a computer. The communication path may utilize a network such as a local area network (LAN).

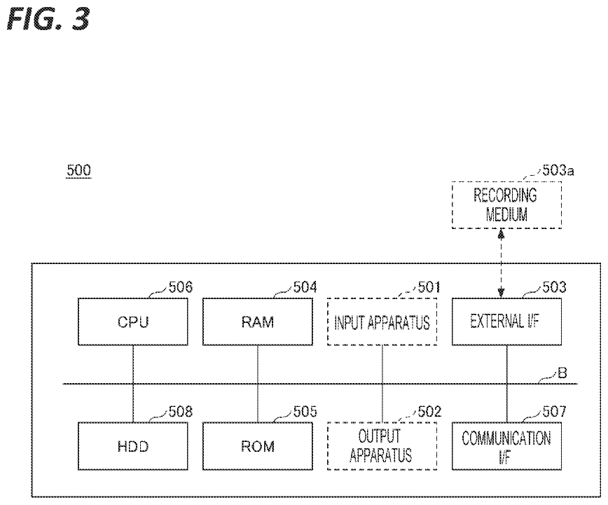

The control device 7 is implemented by, for example, a computer 500 having the hardware configuration illustrated in FIG. 3. FIG. 3 is a hardware configuration diagram of an example of a computer.

A computer 500 of FIG. 3 includes an input apparatus 501, an output apparatus 502, an external interface (I/F) 503, a random access memory (RAM) 504, a read only memory (ROM) 505, a central processing unit (CPU) 506, a communication I/F 507, and a hard disk drive (HDD) 508, and the respective elements are connected to each other via a bus B. The input apparatus 501 and the output apparatus 502 may be connected and used when necessary.

The input apparatus 501 is a keyboard, mouse, or touch panel, and is used by an operator to input each operation signal. The output apparatus 502 is, for example, a display, and displays the processing result by the computer 500. The communication I/F 507 is an interface for connecting the computer 500 to the network. The HDD 508 is an example of a non-volatile storage apparatus that stores programs and data.

The external I/F 503 is an interface with an external apparatus. The computer 500 may read and/or write to a recording medium 503a such as a secure digital (SD) memory card via the external I/F 503. The ROM 505 is an example of a non-volatile semiconductor memory (storage apparatus) in which programs and data are stored. The RAM 504 is an example of a volatile semiconductor memory (storage apparatus) in which programs and data are temporarily held.

The CPU 506 is an arithmetic unit that implements the entire control and functions of the computer 500 by reading a program or data from a storage apparatus such as the ROM 505 or the HDD 508 onto the RAM 504 and executing the process.

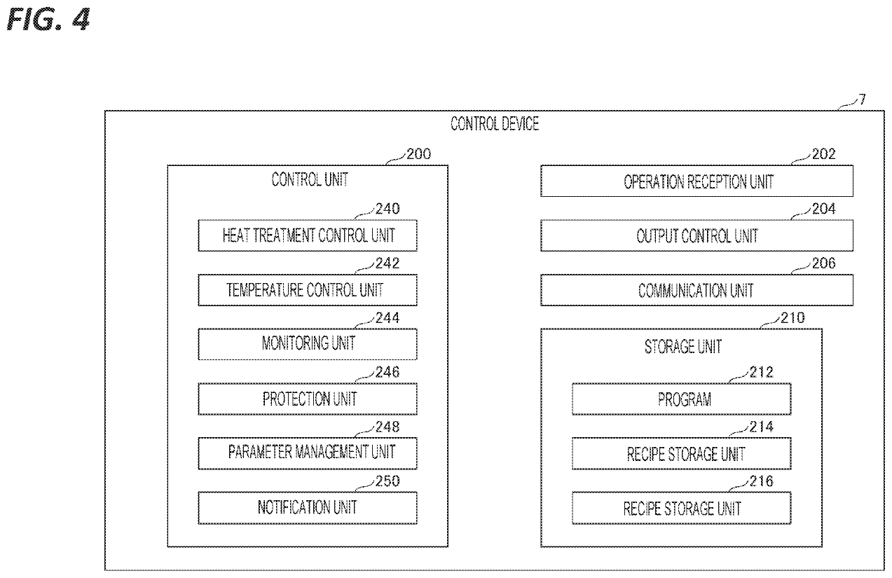

The control device 7 illustrated in FIG. 1 may implement various functions illustrated in FIG. 4 when the computer 500 including the hardware configuration illustrated in FIG. 3 executes process according to the program.

FIG. 4 a diagram illustrating an example of a functional configuration of a control device according to the present embodiment. The control device 7 illustrated in FIG. 4 includes a control unit 200, an operation reception unit 202, an output control unit 204, a communication unit 206, and a storage unit 210.

The storage unit 210 in FIG. 4 stores a program 212, a recipe storage unit 214, and a parameter storage unit 216. The storage unit 210 may be implemented by the HDD 508, or may be implemented by a storage apparatus communicably connected via a network. The program 212 is an example of a program that controls the entire operation of the film forming apparatus 1. The program for controlling the entire operation of the film forming apparatus 1 also includes a program for implementing the protection function of the stationary wafer W in the present embodiment.

The recipe storage unit 214 stores recipes in which processing steps to be executed by the film forming apparatus 1 are set. The parameter storage unit 216 stores parameters needed for the process and parameters of the protection function of the stationary wafer W in the present embodiment.

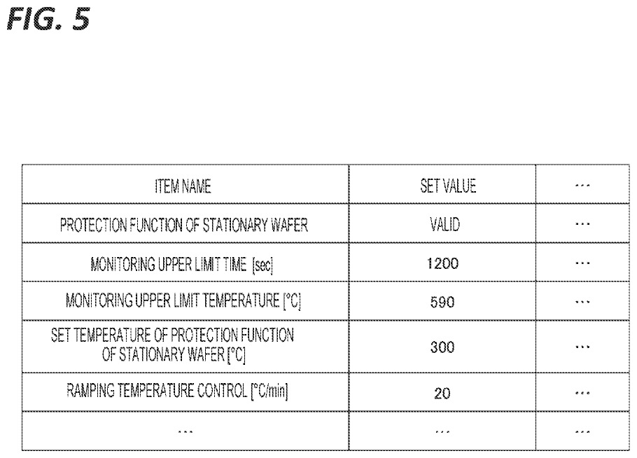

FIG. 5 is a configuration diagram illustrating an example of parameters of the protection function of the stationary wafer W. The parameters of the protection function of the stationary wafer W illustrated in FIG. 5 are items of the protection function of the stationary wafer W, the monitoring upper limit time, the monitoring upper limit temperature, the set temperature of the protection function of the stationary wafer W, and the ramping temperature control.

The item “protection function of stationary wafer” is set to “valid” when the protection function of the stationary wafer W is used, and is set to “invalid” when the protection function of the stationary wafer W is not used. In the item “monitoring upper limit time,” the time from when a monitoring condition (to be described later) is satisfied until the temperature of the heater 33 is started to be lowered by the protection function of the stationary wafer W, is set.

The item “monitoring upper limit temperature” sets a temperature to be compared with the set temperature of the heater 33, and is used for the condition that the set temperature of the heater 33 included in the monitoring condition is equal to or higher than the monitoring upper limit temperature. The item “set temperature of protection function of stationary wafer” refers to the set temperature of the heater 33 that is changed when the monitoring upper limit time elapses while the monitoring condition (to be described later) is satisfied. In the item “ramping temperature control,” the rate of temperature change per unit time when the temperature of the heater 33 is lowered by the protection function of the stationary wafer W, is set.

Referring back to FIG. 4, the control unit 200 controls the film forming apparatus 1 as a whole. The entire control of the film forming apparatus 1 includes a control of a process for storing recipes based on the operation received from the operator, a control of a process for storing parameters of the protection function of the stationary wafer W, a control of the film forming process according to the recipes, and a control of a process of the protection function of the stationary wafer W.

The control unit 200 is implemented when the CPU 506 executes the process described in a program such as the program 212. The control unit 200 in FIG. 4 has a configuration that includes a heat treatment control unit 240, a temperature control unit 242, a monitoring unit 244, a protection unit 246, a parameter management unit 248, and a notification unit 250.

The heat treatment control unit 240 controls the operation of the film forming apparatus 1 such that the film forming process is performed under the processing conditions indicated by the recipe. The temperature control unit 242 controls the output of the heater 33 according to the set temperature of the heater 33. The monitoring unit 244 monitors the processing container 11 in which the wafers W are accommodated based on the monitoring conditions (to be described later). The monitoring unit 244 monitors whether the processing container 11 in which the wafers W are accommodated satisfies the monitoring conditions (to be described later). The protection unit 246 performs a control such that the set temperature of the heater 33 is changed to the set temperature of the protection function of the stationary wafer when the monitoring upper limit time has passed while the monitoring conditions (to be described later) are satisfied. The protection unit 246 performs a control to adjust the speed of lowering the set temperature of the heater 33 according to the set value set for the ramping temperature control.

The parameter management unit 248 stores and manages parameters needed for the protection function of the stationary wafer in the parameter storage unit 216. When the set temperature of the heater 33 is changed by the protection function of the stationary wafer, the notification unit 250 notifies the operator that the set temperature of the heater 33 has been changed to the set temperature of the protection function of the stationary wafer. The notification by the notification unit 250 may be performed by displaying the screen of the control device 7, by sending an e-mail to the e-mail address of the operator, by turning on a lamp, or by outputting a sound.

The operation reception unit 202 receives various operations performed by the operator on the input apparatus 501. The output control unit 204 displays various screens on the output apparatus 502 under the control of the control unit 200. The operation reception unit 202 is implemented when the CPU 506 controls the input apparatus 501 according to the program 212. The output control unit 204 is implemented when the CPU 506 controls the output apparatus 502 according to the program 212. Various operations performed by the operator on the input apparatus 501 refer to operations performed by the operator on the operation reception unit 202 in order to cause the CPU 506 to execute a process. The output control unit 204 displays various screens and outputs sounds under the control of the control unit 200.

The communication unit 206 communicates via a network. The communication unit 206 is implemented when the CPU 506 executes the program 212 to control the communication I/F 507 according to the program 212.

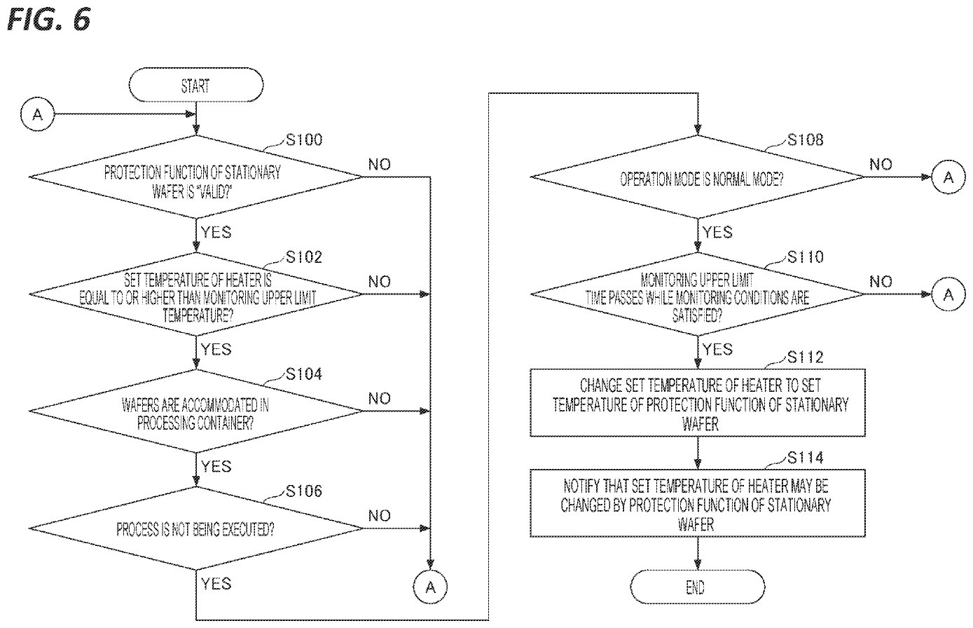

The film forming apparatus 1 according to the present embodiment controls the protection function of the stationary wafers W as illustrated in, for example, FIG. 6. FIG. 6 is a flowchart illustrating an example of a process of the protection function of the stationary wafers W of the film forming apparatus according to the present embodiment.

In step S100, the monitoring unit 244 of the film forming apparatus 1 determines whether the set value of the item “protection function of stationary wafer” included in the parameter of the protection function for stationary wafers W in FIG. 5 is “valid.” When it is determined that the set value of the item “protection function of stationary wafer” is not “valid,” the monitoring unit 244 repeats the process of step S100.

When it is determined that the set value of the item “protection function of stationary wafer” is “valid,” the monitoring unit 244 performs the process of step S102. In step S102, the monitoring unit 244 compares the set value of the item “monitoring upper limit temperature” included in the parameters of the protection function of the stationary wafer W in FIG. 5 with the set temperature of the heater 33 to determine whether the temperature is equal to or higher than the set value of “monitoring upper limit temperature.” When it is determined that the set temperature of the heater 33 is not equal to or higher than the set value of the item “monitoring upper limit temperature,” the monitoring unit 244 returns to the process of step S100.

When it is determined that the set temperature of the heater 33 is equal to or higher than the set value of the item “monitoring upper limit temperature,” the monitoring unit 244 performs the process of step S104. In step S104, the monitoring unit 244 determines whether one or more wafers W are accommodated in the processing container 11. Whether one or more wafers W are accommodated in the processing container 11 may be determined by determining whether one or more wafers W are accommodated in a processing module (PM). When it is determined that one or more wafers W are not accommodated in the processing container 11, the monitoring unit 244 returns to the process of step S100.

When it is determined that one or more wafers W are accommodated in the processing container 11, the monitoring unit 244 performs the process of step S106. In step S106, the monitoring unit 244 determines whether the recipe-based process is being executed (whether the process is being executed). When it is determined that the recipe-based process is being executed, the monitoring unit 244 returns to the process of step S100.

When it is determined that the recipe-based process is not being executed, the monitoring unit 244 performs the process of step S108. In step S108, the monitoring unit 244 determines whether the operation mode is the normal mode when the processing container 11 has operation modes of the normal mode and the maintenance mode. The maintenance mode is an operation mode to be used for maintenance of the processing container 11. When it is determined that the operation mode is not the normal mode, the monitoring unit 244 returns to the process of step S100.

When it is determined that the operation mode is the normal mode, the monitoring unit 244 and protection unit 246 perform the process of step S110. In step S110, the monitoring unit 244 notifies the protection unit 246 that the monitoring condition of the protection function of the stationary wafer W has been satisfied.

In the case of FIG. 6, a state in which the monitoring condition for the protection function of the stationary wafer W has been satisfied refers to a state in which all of steps S100 to S108 are determined to be “YES.” In FIG. 6, the set value of the item “protection function of stationary wafer” is “valid,” the set temperature of the heater 33 is equal to or higher than the set value of the item “monitoring upper limit temperature,” one or more wafers W are accommodated in the processing container 11, and a recipe-based process is being executed. Further, when the operation mode is the normal mode, the monitoring condition of the protection function of the stationary wafer W is satisfied.

The flowchart of FIG. 6 is an example, and a part of the process of steps S100 to S108 may be omitted. For example, at least one of steps S106 and S108 may be omitted.

When measuring the elapsed time for determining whether the monitoring upper limit time has passed while the monitoring condition is satisfied has not started, the protection unit 246 starts measuring the elapsed time. The protection unit 246 compares the measured elapsed time with the set value of the item “monitoring upper limit time” included in the parameters of the protection function of the stationary wafer W in FIG. 5 to determine whether the monitoring upper limit time has passed while the monitoring condition is satisfied.

When it is determined that the monitoring upper limit time has passed while the monitoring condition is satisfied, the protection unit 246 performs the process of step S112. Further, when it is determined that the monitoring upper limit time has not passed while the monitoring condition is satisfied, the monitoring unit 244 returns to the process of step S100.

In step S112, the protection unit 246 performs a control to change the set temperature of the heater 33 to the set value of the item “set temperature of protection function of stationary wafer” included in the parameters of the protection function of the stationary wafer W in FIG. 5. The protection unit 246 may perform a control to adjust the rate at which the set temperature of the heater 33 is lowered according to the set value of the item “ramping temperature control” included in the parameters of the protection function of the stationary wafer W in FIG. 5.

Therefore, the film forming apparatus 1 according to the present embodiment may lower the set temperature of the heater 33 so that the stationary wafers W are not scrapped due to unacceptable damage caused by the heating from the heater 33.

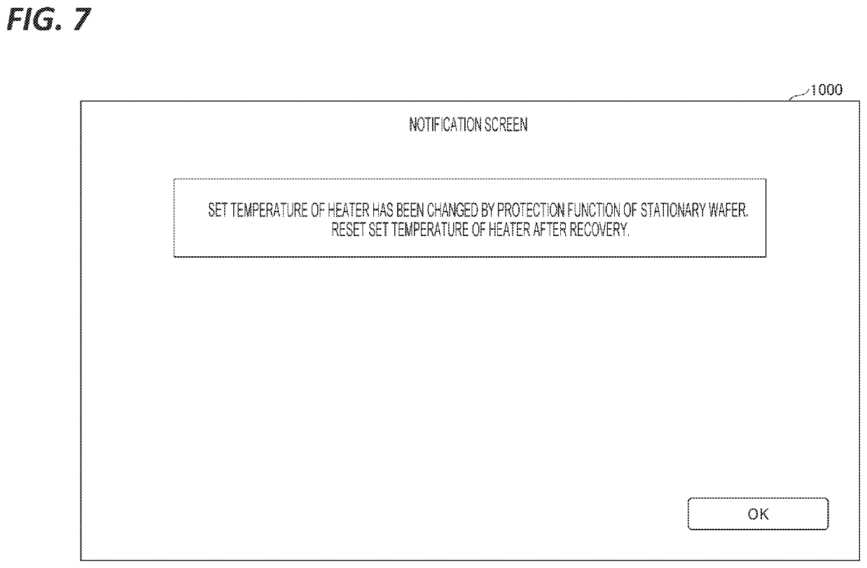

In step S114, the notification unit 250 notify the operator that the set temperature of the heater 33 has been changed by the protection function of the stationary wafer.” The notification by the notification unit 250 may be performed by a notification screen 1000 as illustrated in, for example, FIG. 7, by sending an e-mail to the e-mail address of the operator, by turning on a lamp, or by outputting a sound. FIG. 7 is an image diagram of an example of the notification screen. The notification screen 1000 is an example displaying that the set temperature of the heater 33 has been changed by the protection function of the stationary wafer and that it is necessary to reset the set temperature of the heater 33 after recovery.

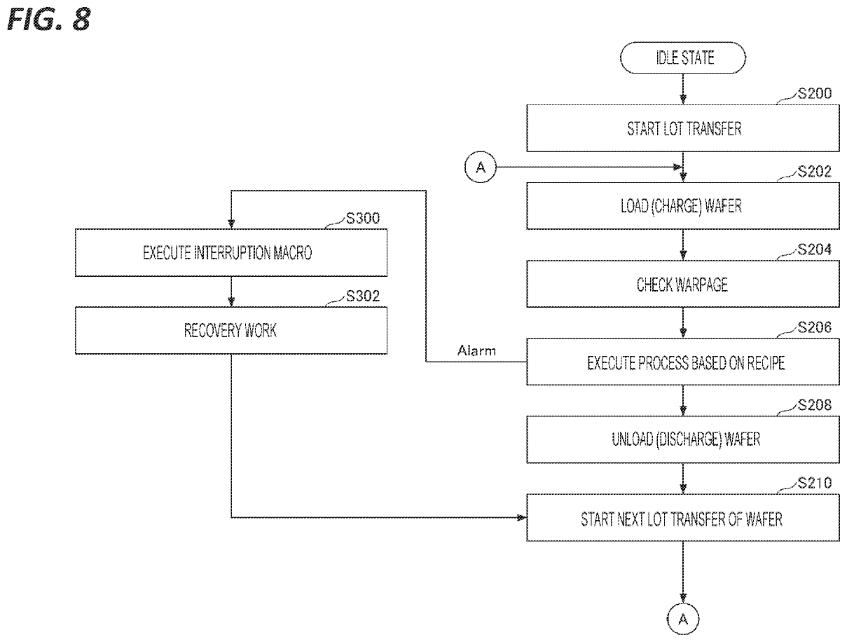

FIG. 8 is a flowchart of a process execution for a wafer W. The film forming apparatus 1 in an idle state starts performing a lot transfer of wafers W in step S200. In step S202, the film forming apparatus 1 performs a wafer charge, which is a wafer transfer for loading the wafers W into the processing container 11. In step S204, the film forming apparatus 1 checks the warpage of the wafer W loaded into the processing container 11. The warpage check in step S204 is a process of waiting until a temporary change in the shape of the wafer W due to heating is resolved.

In step S206, the film forming apparatus 1 executes the process based on the recipe. When an alarm is generated during execution of the process, the film forming apparatus 1 executes an interruption macro corresponding to the generated alarm in step S300. The interruption macro is a collection of commands that may be set arbitrarily.

Therefore, when the process is being executed, the film forming apparatus 1 may use the interruption macro of step S300 to lower the set temperature of the heater 33 so that the stationary wafer W is not unacceptably damaged by the heating from the heater 33. In step S302, the operator performs a necessary recovery work on the film forming apparatus 1. After the recovery work by the operator is completed, the film forming apparatus 1 starts the next lot transfer of the wafer W in step S210 according to the operation by the operator.

When the process based on the recipe of step S206 is completed, the film forming apparatus 1 performs a wafer discharge, which is a wafer transfer for unloading the wafer W from the processing container 11 in step S208. When the wafer transfer for unloading the wafers W from the processing container 11 is completed, the film forming apparatus 1 starts the next lot transfer of the wafer W in step S210.

In the flowchart illustrated in FIG. 8, in a case where an alarm (error) is generated when the wafer W is loaded in step S202 or when the wafer W is unloaded in step S208, the stationary wafers W may remain in the processing container 11. However, since the film forming apparatus 1 is not executing the process, the set temperature of the heater 33 may not be lowered using the interruption macro in step S300.

Therefore, even when the stationary wafers W remain in the processing container 1 during the period in which the interruption macro may not be used, the film forming apparatus 1 according to the present embodiment is provided with the protection function of the stationary wafer W capable of lowering the set temperature of the heater 33. The elapsed time for determining whether the monitoring upper limit time has passed while the monitoring conditions are satisfied is initialized by starting execution of the process based on the recipe in step S206. In addition, the measurement of the elapsed time for determining whether the monitoring upper limit time has passed while the monitoring conditions are satisfied is stopped until the execution of the process based on the recipe in step S206 is completed.

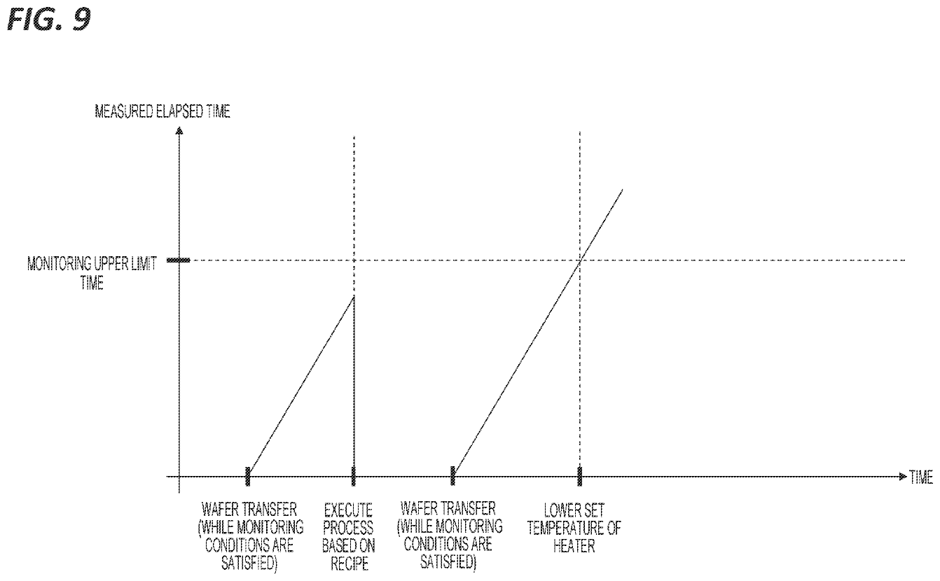

For example, FIG. 9 illustrates changes in the elapsed time measured to determine whether the monitoring upper limit time has passed while the monitoring conditions are satisfied. FIG. 9 is a diagram illustrating an example of changes in the elapsed time measured to determine whether the monitoring upper limit time has passed while the monitoring conditions are satisfied.

As illustrated in FIG. 9, for example, when the monitoring conditions are satisfied by the wafer transfer in step S202, the measured elapsed time starts to increase. When no alarm is generated during wafer transfer, before the measured elapsed time exceeds the set value of the item “monitoring upper limit time” included in the parameters of the protection function of the stationary wafer W in FIG. 5, the film forming apparatus 1 starts executing the process based on the recipe in step S206.

Therefore, when no alarm is generated during wafer transfer, the film forming apparatus 1 initializes the measured elapsed time, and stops measuring the elapsed time until the execution of the process based on the recipe in step S206 is completed.

When the execution of the process is completed, the measured elapsed time reaches a state in which the monitoring state is satisfied due to the wafer transfer in step S208, and starts increasing. In the example of FIG. 9, an alarm is generated during wafer transfer in step S208, and the elapsed time exceeds the set value of the item “monitoring upper limit time” included in the parameters of the protection function of the stationary wafer Win FIG. 5.

Therefore, in the example of FIG. 9, a temperature drop control is performed to change the set temperature of the heater 33 to the set value of the item “set temperature of protection function of stationary wafer” included in the parameters of the protection function of the stationary wafer W illustrated in FIG. 5.

In the flowchart illustrated in FIG. 8, the film forming apparatus 1 may alternately perform unloading the wafer W from the processing container 11 in step S208 and loading the wafer W into the processing container 11 in step S202, which is a next lot transfer.

As described above, according to the present embodiment, it is possible to provide a technique for suppressing damage due to heating of the wafers W retained in the processing container 11.

For example, in the present embodiment, one control device 7 corresponds to one film forming apparatus 1, but one control device 7 may correspond to a plurality of film forming apparatuses 1. The function of the control device 7 may be provided in a host computer or a cloud computer communicably connected to the film forming apparatus 1. A film forming apparatus, a plasma processing apparatus, or an etching apparatus, in which a process of heating a substrate is performed, is an example of the heat treatment apparatus. Further, although the present embodiment describes an example of the film forming apparatus 1 that utilizes plasma, the present disclose is not limited thereto.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A heat treatment apparatus comprising:
a processing container configured to accommodate a processing target;
a heater configured to heat the processing target accommodated in the processing container; and
a controller configured to control an overall operation of the heat treatment apparatus,
wherein the controller is configured to:
control heating by the heater according to a set temperature of the heater;
monitor the processing container in which the processing target is accommodated based on a monitoring condition of a protection function for the processing target; and
when an upper limit time of monitoring elapses while the monitoring condition is being satisfied, change the set temperature of the heater to a set temperature of the protection function.

2. The heat treatment apparatus according to claim 1, wherein, when the protection function is capable of being set to be valid or invalid, and the protection function is set to be valid, the controller is configured to monitor whether a condition that the set temperature of the heater included in the monitoring condition is equal to or higher than an upper limit temperature of monitoring and a condition that one or more processing targets are accommodated in the processing container have been satisfied.

3. The heat treatment apparatus according to claim 1, wherein, when the protection function is capable of being set to be valid or invalid, and the protection function is set to be valid, the controller is configured to monitor whether a condition that the set temperature of the heater included in the monitoring condition is equal to or higher than an upper limit temperature of monitoring, a condition that one or more processing targets are accommodated in the processing container, and a condition that a heat treatment is not being executed based on wafer processing information have been satisfied.

4. The heat treatment apparatus according to claim 3, wherein, when an operation mode of the processing container includes a normal mode and a maintenance mode, the controller is configured to further monitor whether a condition that the operation mode of the processing container included in the monitoring condition is the normal mode has been satisfied.

5. The heat treatment apparatus according to claim 4, wherein, when the upper limit time of monitoring elapses while the monitoring condition is being satisfied, the controller is configured to lower the set temperature of the heater to the set temperature of the protection function according to a set value of a ramping temperature control of the protection function.

6. The heat treatment apparatus according to claim 5, wherein the controller is further configured to notify an operator that the set temperature of the heater has changed to the set temperature of the protection function.

7. The heat treatment apparatus according to claim 6, wherein the controller is configured to initialize an elapsed time measured for determining whether the upper limit time of monitoring has elapsed while the monitoring condition is being satisfied, at a start of the heat treatment based on the wafer processing information.

8. The heat treatment apparatus according to claim 2, wherein, when an operation mode of the processing container includes a normal mode and a maintenance mode, the controller is configured to further monitor whether a condition that the operation mode of the processing container included in the monitoring condition is the normal mode has been satisfied.

9. The heat treatment apparatus according to claim 1, wherein, when the upper limit time of monitoring elapses while the monitoring condition is being satisfied, the controller is configured to lower the set temperature of the heater to the set temperature of the protection function according to a set value of a ramping temperature control of the protection function.

10. The heat treatment apparatus according to claim 1, wherein the controller is further configured to notify an operator that the set temperature of the heater has changed to the set temperature of the protection function.

11. The heat treatment apparatus according to claim 1, wherein the controller is configured to initialize an elapsed time measured for determining whether the upper limit time of monitoring has elapsed while the monitoring condition is being satisfied, at a start of the heat treatment based on the wafer processing information.

12. A method of protecting a processing target, the method comprising:
providing a heat treatment apparatus including:
a processing container configured to accommodate the processing target;
a heater configured to heat the processing target accommodated in the processing container; and
a controller configured to control an overall operation of the heat treatment apparatus,
controlling heating by the heater according to a set temperature of the heater;
monitoring the processing container in which the processing target is accommodated based on a monitoring condition of a protection function for the processing target; and
when an upper limit time of monitoring elapses while the monitoring condition is being satisfied, changing the set temperature of the heater to a set temperature of the protection function.

13. A non-transitory computer-readable storage medium having stored therein a program that causes a controller of a heat treatment apparatus to execute a process including:
controlling heating by a heater of the heat treatment apparatus according to a set temperature of the heater;
monitoring a processing container of the heat treatment apparatus in which a processing target is accommodated based on a monitoring condition of a protection function of the processing target; and
when an upper limit time of monitoring elapses while the monitoring condition is being satisfied, changing the set temperature of the heater to a set temperature of the protection function.
